(19) United States
(12) Patent Application Publication
(10) Pub. No.: US 2025/0341579 A1
(43) Pub. Date: Nov. 6, 2025

(54) SYSTEM AND METHOD FOR PREDICTING A STATE-OF-HEALTH OF AN ELECTRIC ENERGY STORAGE DEVICE

(71) Applicants: HYUNDAI MOTOR COMPANY, Seoul (KR); KIA CORPORATION, Seoul (KR); UIF (UNIVERSITY INDUSTRY FOUNDATION), YONSEI UNIVERSITY, Seoul (KR)

(72) Inventors: Young Woo Noh, Guri-si (KR); Jong Moon Chung, Seoul (KR); Jeong Eon Park, Yongin-si (KR)

(73) Assignees: HYUNDAI MOTOR COMPANY, Seoul (KR); KIA CORPORATION, Seoul (KR); UIF (UNIVERSITY INDUSTRY FOUNDATION), YONSEI UNIVERSITY, Seoul (KR)

(21) Appl. No.: 18/934,764

(22) Filed: Nov. 1, 2024

(30) Foreign Application Priority Data
May 2, 2024 (KR) 10-2024-0058466

(51) Int. Cl. G01R 31/367; B60L 3/00; G01R 31/371; G01R 31/382; G01R 31/392; G08B 21/18

(52) U.S. Cl. CPC G01R 31/367; B60L 3/0046; G01R 31/371; G01R 31/382; G01R 31/392; G08B 21/185

(57) ABSTRACT

A system for predicting a State of Health (SoH) of an electric energy storage device mounted in a vehicle includes a data collection unit configured to acquire charge/discharge data of the electric energy storage device. The system further includes a vehicle control unit configured to acquire an SoH prediction neural network model for predicting an SoH for each charge/discharge cycle of the electric energy storage device, based on first charge/discharge data of the electric energy storage device acquired by the data collection unit. The vehicle control unit is also configured to predict and determine the SoH for each charge/discharge cycle of the electric energy storage device using the SoH prediction neural network model.

### CROSS-REFERENCE TO RELATED APPLICATION

This application claims, under 35 U.S.C. § 119 (a), the benefit of and priority to Korean Patent Application No. 10-2024-0058466 filed on May 2, 2024, the entire contents of which are incorporated herein by reference.

### BACKGROUND

### (a) Technical Field

The present disclosure relates to relates to a system and a method for predicting a State of Health (SoH) of an electric energy storage device using a neural network model.

### (b) Background Art

As the demand for eco-friendly vehicles increases, research and development to apply a supercapacitor to a vehicle for the purpose of improving fuel efficiency and providing high-output power assistance are being actively performed.

Such a supercapacitor is an electric energy storage device based on non-faradic response and has a long lifespan and a high power density. Deterioration of the supercapacitor has large nonlinearity and is influenced by various factors, and accordingly it is essential to evaluate the durability and lifespan of the supercapacitor for stable power operation.

However, because the life cycle of the supercapacitor is quite long, i.e., hundreds of thousands of cycles, there is a problem that it takes a very long time to evaluate the lifespan of the supercapacitor.

The above information disclosed in this Background section is only for enhancement of understanding of the background of the present disclosure, and therefore it may contain information that does not form the prior art that is already known in this country to a person of ordinary skill in the art.

### SUMMARY OF THE DISCLOSURE

The present disclosure has been made in an effort to solve the above-described problems associated with prior art. An object of the present disclosure is to provide a system and a method for predicting a State of Health (SoH) of an electric energy storage device. The system and method are capable of predicting SoH for each charge/discharge cycle of the electric energy storage device based on first charge/discharge data of the electric energy storage device.

The object of the present disclosure is not limited to the object mentioned above, and other objects of the present disclosure not mentioned above should be clearly understood by those having ordinary skill in the art from the present disclosure.

In one aspect, the present disclosure provides a system for predicting a State of Health (SoH) of an electric energy storage device mounted in a vehicle. The system includes a data collection unit configured to acquire charge/discharge data of the electric energy storage device,. The system further includes a vehicle control unit configured to acquire an SoH prediction neural network model for predicting SoH for each charge/discharge cycle of the electric energy storage device, based on first charge/discharge data of the electric energy storage device acquired by the data collection unit. The vehicle control unit is further configured to predict and determine the SoH for each charge/discharge cycle of the electric energy storage device using the SoH prediction neural network model.

In an embodiment, the vehicle control unit may determine a driver type based on the type of a road on which the vehicle travels. The vehicle control unit may further download a first SoH prediction neural network model among SoH prediction neural network models for respective driver types stored in a data server based on the determined driver type.

In another embodiment, the vehicle control unit may download, in a case where a determination is made that the driver type has been changed during a driving of the vehicle, a second SoH prediction neural network model from the data server based on the changed driver type.

In still another embodiment, the system may further include a display device configured to display the SoH for each charge/discharge cycle of the electric energy storage device predicted by the vehicle control unit.

In yet another embodiment, the display device may selectively display a replacement alarm for the electric energy storage device based on the SoH for each charge/discharge cycle of the electric energy storage device predicted by the vehicle control unit.

In still yet another embodiment, the vehicle control unit may determine a critical charge/discharge cycle for a replacement alarm for the electric energy storage device based on the SoH for each charge/discharge cycle of the electric energy storage device. The vehicle control unit may further output the replacement alarm for the electric energy storage device through the display device in a case where an actual charge/discharge cycle of the electric energy storage device is equal to or longer than the critical charge/discharge cycle.

In a further embodiment, the SoH prediction neural network model may be preconfigured for each driver type through neural network model training and may be stored in a data server.

In another aspect, the present disclosure provides a method of predicting a State of Health (SoH) of an electric energy storage device mounted in a vehicle. The method includes acquiring, by a data collection unit, first charge/discharge data of the electric energy storage device. The method further includes acquiring, by a vehicle control unit, an SoH prediction neural network model for predicting an SoH for each charge/discharge cycle of the electric energy storage device, based on the first charge/discharge data. The method further includes predicting and determining, by the vehicle control unit, the SoH for each charge/discharge cycle of the electric energy storage device using the acquired SoH prediction neural network model.

In an embodiment, the method further includes preconfiguring, by a deep learning processor, the SoH prediction neural network model for each driver type through neural network model training and neural network model evaluation by a deep learning processor. The method further includes storing, by a data server, the SoH prediction neural network model for each driver type.

In another embodiment, the neural network model training by the deep learning processor may include dividing neural network model training data into training data, validation data, and test data. The neural network model training by the deep learning processor may further include generating final input parameters for the neural network model training from the training data and the validation data, determining a curve fitting function based on the training data and the validation data. The neural network model training by the deep learning processor may further include determining final output coordinates for the neural network model training based on the curve fitting function. The neural network model training by the deep learning processor may further include training the SoH prediction neural network model for predicting the SoH for each charge/discharge cycle of the electric energy storage device using the final input parameters and the final output coordinates for the neural network model training.

In still another embodiment, the neural network model evaluation by the deep learning processor may include selecting test input parameters for evaluating the trained SoH prediction neural network model from the test data. The neural network model evaluation by the deep learning processor may further include outputting prediction coordinates for predicting the SoH for each charge/discharge cycle of the electric energy storage device from the trained SoH prediction neural network model, based on the test input parameters. The neural network model evaluation by the deep learning processor may further include executing performance evaluation of the trained SoH prediction neural network model based on the prediction coordinates output from the trained SoH prediction neural network model. The neural network model evaluation by the deep learning processor may further include storing, in a case where a determination is made through the performance evaluation that a target performance of the trained SoH prediction neural network model is achieved, the trained SoH prediction neural network model in the data server.

Other aspects and embodiments of the present disclosure are discussed below.

It should be understood that the term “vehicle,” “vehicular,” or other similar terms as used herein include motor vehicles in general, such as passenger automobiles including sport utility vehicles (SUV), buses, trucks, various commercial vehicles, watercraft including a variety of boats and ships, aircraft, and the like. The term includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example, vehicles powered by both electricity and gasoline.

The above and other features of the present disclosure are discussed below.

### BRIEF DESCRIPTION OF THE DRAWINGS

The above and other features of the present disclosure are described in detail with reference to embodiments thereof illustrated in the accompanying drawings, which are intended to illustrate the present disclosure and are not intended to limit the present disclosure, and wherein:

FIG. 1 is a configuration diagram showing a system for predicting a State of Health (SoH) of an electric energy storage device according to an embodiment of the present disclosure;

FIG. 2 is a flowchart showing a method of predicting the SoH of the electric energy storage device according to an embodiment of the present disclosure;

FIG. 3 is a flowchart showing a method of constructing a neural network model for predicting the SoH of the electric energy storage device according to an embodiment of the present disclosure;

FIG. 4 is a flowchart showing a final output coordinate extraction process according to an embodiment of the present disclosure;

FIG. 5 is a diagram showing a graph of a curve fitting function generated in a neural network model training process according to an embodiment of the present disclosure;

FIG. 6 is a diagram showing a curvature graph acquired in a neural network model training process according to an embodiment of the present disclosure;

FIG. 7 is a diagram showing final output coordinates for neural network model training selected in a neural network model training process according to an embodiment of the present disclosure; and

FIG. 8 is a diagram showing capacitance values of an evaluation curve fitting function generated in a neural network model evaluation process according to an embodiment of the present disclosure compared with real capacitance values.

It should be understood that the appended drawings are not necessarily to scale and present a somewhat simplified representation of various features illustrating the basic principles of the present disclosure. The specific design features of the present disclosure as disclosed herein, including, for example, specific dimensions, orientations, locations, and shapes, are determined in part by the particular intended application and use environment.

In the figures, same reference numbers refer to the same or equivalent parts of the present disclosure throughout the drawings.

### DETAILED DESCRIPTION

Hereinafter, references are made in detail to various embodiments of the present disclosure, examples of which are illustrated in the accompanying drawings and described below. While the present disclosure is described in conjunction with embodiments, it should be understood that the present disclosure is not limited to the embodiments. On the contrary, the present disclosure is intended to cover not only the embodiments, but also various alternatives, modifications, equivalents and other embodiments, within the spirit and scope of the present disclosure as defined by the appended claims.

It should be understood that, although the terms “first”, “second”, etc. may be used herein to describe various elements, these elements should not be limited by these terms. These terms are only used to distinguish one element from another. For example, a first element may be termed as a second element, and similarly a second element may be termed as a first element, without departing from the scope of the embodiments of the present disclosure.

Wherever possible, the same reference numbers are used throughout the drawings to refer to the same or like parts. The terminologies used herein are intended to describe particular embodiments only and are not intended to limit embodiments of the present disclosure. As used herein, the singular forms “a”, “an”, and “the” are intended to include the plural forms as well, unless the context clearly indicates otherwise. It should be further understood that the terms “comprise”, “include”, and “have” used herein specify the presence of stated components, steps, operations, and/or elements but do not preclude the presence or addition of one or more other components, steps, operations, and/or elements.

The following examples illustrate the disclosure and are not intended to limit the same.

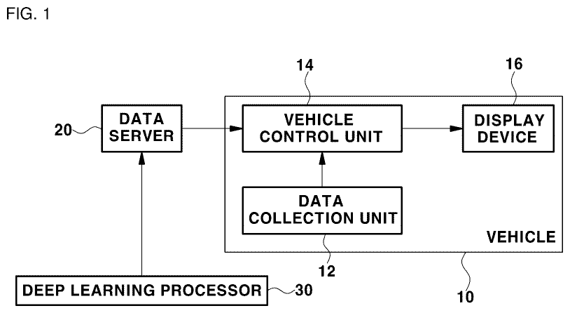

As shown in FIG. 1, a system for predicting a State of Health (SoH) of an electric energy storage device according to an embodiment of the present disclosure may include a data collection unit 12, a vehicle control unit 14, and a display device 16, provided in a vehicle 10.

The vehicle 10 is equipped with an electric energy storage device, such as a supercapacitor, as a power source of the vehicle. The supercapacitor is an electric energy storage device having the characteristics of a long lifespan and a high power density. The supercapacitor charges electric energy supplied from an electricity generator such as a fuel cell mounted in the vehicle 10.

The SoH of the electric energy storage device may represent a performance state and a lifespan state of the electric energy storage device and may vary based on an initial capacitance and a current capacitance (i.e., a real-time capacitance). More specifically, the SoH of the electric energy storage device may be calculated as a ratio value (%) of the real-time capacitance to the initial capacitance.

The data collection unit 12 collects and stores charge/discharge data of the electric energy storage device that is actually mounted in the vehicle 10. As an example, the data collection unit 12 may include various sensors for detecting and acquiring the charge/discharge data of the electric energy storage device. The data collection unit 12 may also include a memory for storing the detected and acquired charge/discharge data. As another example, the data collection unit 12 may be a battery management system (BMS) or a capacitor management system (CMS) that monitors the charge/discharge data of the electric energy storage device. Further, the memory may be replaced with a memory built in the vehicle control unit 14.

The charge/discharge data may be detected and acquired for each charge/discharge cycle of the electric energy storage device and may include voltage, current, temperature, capacitance, coulombic efficiency, etc. of the electric energy storage device. The charge/discharge data includes indicators and factors that are correlated with the performance and deterioration of the electric energy storage device. The data collection unit 12 provides first charge/discharge data of the electric energy storage device to the vehicle control unit 14. The first charge/discharge data is charge/discharge data acquired during a first charge/discharge cycle of the electric energy storage device.

The vehicle control unit 14 stores the first charge/discharge data of the electric energy storage device acquired through the data collection unit 12 in the built-in memory. The vehicle control unit 14 predicts and decides the SoH for each charge/discharge cycle of the electric energy storage device using an SoH prediction neural network model configured to predict the SoH for each charge/discharge cycle of the electric energy storage device based on the first charge/discharge data. In other words, the SoH prediction neural network model is a model for determining SoH for the entire charge/discharge cycle of the electric energy storage device based on the first charge/discharge data of the electric energy storage device.

The performance and deterioration of the electric energy storage device may vary depending on a driver type of the vehicle 10. Therefore, the SoH prediction neural network model is preconfigured for each driver type and is stored in a data server 20.

More specifically, the SoH prediction neural network model may be built through a deep learning processor 30 provided in a separate computing device for research and development of vehicle manufacturers and may be preconfigured for each driver type through artificial neural network training using the deep learning processor 30 and stored in the data server 20.

Accordingly, the vehicle control unit 14 downloads and acquires a predetermined SoH prediction neural network model from the data server 20 based on a real-time driver type. The data server 20 may be a server independently managed by a vehicle manufacturer.

The driver type may be classified and determined based on types of roads on which the vehicle 10 travels. The drive road types refer to types of roads on which the vehicle 10 has traveled so far. Accordingly, the driver type is determined based on the types of roads on which the vehicle 10 has traveled from the time when the electric energy storage device was mounted in the vehicle 10 to the present.

Here, the road types may be divided into a city road and a highway (i.e., a road exclusively for automobiles), and the driver type may be determined based on the ratio of the city roads to the highways on which the vehicle 10 has traveled so far. In other words, the vehicle control unit 14 may determine the driver type based on the ratio of driving on the city roads of the vehicle 10 to driving on the highways thereof.

For this purpose, the vehicle control unit 14 may include at least one memory and a processor. A driver type determination model for determining the driver type based on the type of a road on which the vehicle 10 travels may be preconfigured and stored in the memory of the vehicle control unit 14. The processor of the vehicle control unit 14 may determine a real-time driver type using the driver type determination model and may download a predetermined SoH prediction neural network model that matches the determined real-time driver type from the data server 20.

In addition, the city road driving and the highway driving of the vehicle 10 may be determined based on a Global Positioning System (GPS) signal of the vehicle 10. The vehicle control unit 14 may calculate the ratio of the city road driving to the highway driving of the vehicle 10 based on accumulated GPS signals of the vehicle 10 and may determine the driver type in real time based on the calculated ratio. The GPS signals detected while the vehicle 10 is traveling may be accumulated and stored in the memory of the vehicle control unit 14.

For example, in a case where the city road driving is 20% and the highway driving is 80%, the driver type of the vehicle 10 may be determined as a first driver type. In a case where the city road driving and the highway driving are 50%, respectively, the driver type may be determined as a second driver type. Further, in a case where the city road driving is 80% and the highway driving is 20%, the driver type may be determined as a third driver type. The driver type may be divided in more detail by adjusting the ratio of the city road driving to the highway driving.

The vehicle control unit 14 acquires a predetermined SoH prediction neural network model from the data server 20 based on a real-time driver type. In other words, the vehicle control unit 14 downloads, from the data server 20, a first SoH prediction neural network model selected based on the real-time driver type among SoH prediction neural network models for respective driver types stored in the data server 20. Here, the vehicle control unit 14 predicts SoH for each charge/discharge cycle of the electric energy storage device using the downloaded first SoH prediction neural network model.

In this regard, the driver type of the vehicle 10 may be changed during the driving of the vehicle 10. Accordingly, in a case where it is determined that the driver type has been changed during the driving of the vehicle 10, the vehicle control unit 14 additionally downloads a second SoH prediction neural network model selected and determined based on the changed driver type from the data server 20. In this case, the vehicle control unit 14 re-predicts SoH for each charge/discharge cycle of the electric energy storage device using the downloaded second SoH prediction neural network model.

The vehicle control unit 14 determines a critical charge/discharge cycle for generating a replacement alarm for the electric energy storage device based on the SoH for each charge/discharge cycle of the electric energy storage device predicted using the SoH prediction neural network model. For example, the lowest charge/discharge cycle at which the SoH for each charge/discharge cycle of the electric energy storage device reaches or less than a predetermined SoH may be selected as the critical charge/discharge cycle.

The vehicle control unit 14 counts an actual charge/discharge cycle of the electric energy storage device during driving. In a case where the counted actual charge/discharge cycle is equal to or greater than the critical charge/discharge cycle, the vehicle control unit 14 outputs and displays the replacement alarm for notifying a replacement time of the electric energy storage device on the display device 16.

The display device 16 is configured to selectively output and display the replacement alarm for the electric energy storage device. In a case where the critical charge/discharge cycle arrives, the display device 16 displays the replacement alarm for the electric energy storage device to recommend a driver to replace the electric energy storage device. The display device 16 may be an instrument panel provided in the vehicle.

In addition, the display device 16 is configured to display the SoH value for each charge/discharge cycle of the electric energy storage device predicted by the vehicle control unit 14 through the SoH prediction neural network model. In other words, the display device 16 may also output and display a prediction result for SoH for each charge/discharge cycle of the electric energy storage device. For example, the display device 16 may output the SoH value for the entire charge/discharge cycle of the electric energy storage device in a graph form.

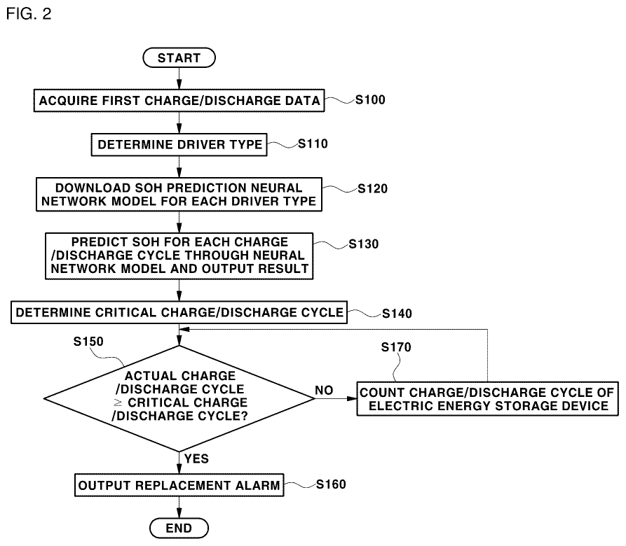

FIG. 2 is a flowchart showing a method of predicting the SoH of the electric energy storage device according to an embodiment of the present disclosure.

As shown in FIG. 2, in step S100, the vehicle control unit 14 acquires first charge/discharge data of the electric energy storage device by the data collection unit 12. The acquired first charge/discharge data may be stored in the memory of the vehicle control unit 14.

In step S110, the vehicle control unit 14 determines a driver type based on a type of a road on which the vehicle 10 travels. Then, in step S120, the vehicle control unit 14 downloads a predetermined SoH prediction neural network model from the data server 20 based on the driver type determined in step S110.

In step S130, the vehicle control unit 14 predicts an SoH for each charge/discharge cycle of the electric energy storage device through the SoH prediction neural network model downloaded in step S120 and outputs the predicted SoH for each charge/discharge cycle on the display device 16. Here, the display device 16 may display the SoH for each charge/discharge cycle in a graph form.

In step S140, the vehicle control unit 14 determines a critical charge/discharge cycle for notification of a replacement time of the electric energy storage device based on the SoH for each charge/discharge cycle predicted in step S130.

Then, in step S150, the vehicle control unit 14 compares the critical charge/discharge cycle determined in step S140 with an actual charge/discharge cycle of the electric energy storage device. As a result of the comparison, in a case where the actual charge/discharge cycle is equal to or greater than the critical charge/discharge cycle (YES in step S150), the vehicle control unit 14 outputs and displays a replacement alarm for notification of arrival of the replacement time of the electric energy storage device, through the display device 16 (S160).

As a result of the comparison in step S150, in a case where the actual charge/discharge cycle is less than the critical charge/discharge cycle (NO in step S150), step S170 is repeatedly executed until the actual charge/discharge cycle reaches the critical charge/discharge cycle. In step S170, the vehicle control unit 14 counts the actual charge/discharge cycle of the electric energy storage device and stores the result in the built-in memory.

By displaying the replacement alarm for the electric energy storage device on the display device 16, it is possible for a driver to recognize the replacement time of the electric energy storage device and replace the electric energy storage device with a new electric energy storage device. Thus, a stable power operation of a vehicle may be achieved.

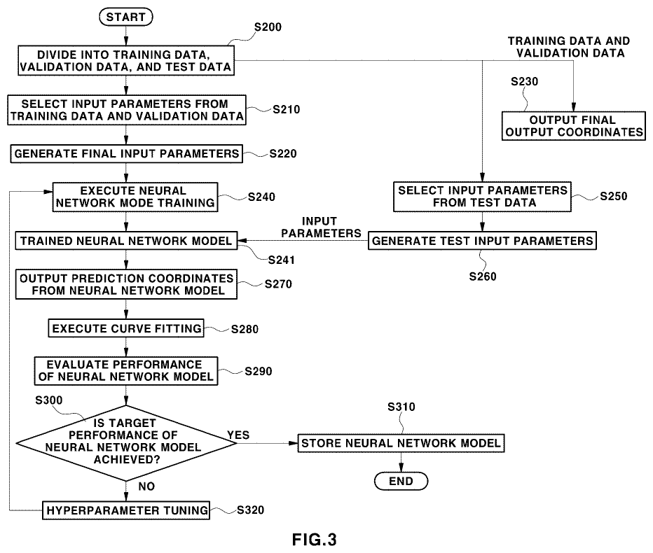

FIG. 3 is a flowchart showing a process of constructing an SoH prediction neural network model of the electric energy storage device.

An SoH prediction neural network model for predicting an SoH for each charge/discharge cycle of the electric energy storage device may be built through the deep learning processor 30 provided in a separate computing device. The computing device may be a device provided in a research and development organization of a vehicle manufacturer for research and development of the SoH prediction neural network model.

Although not specifically shown, the computing device has a database in which data for training, validation and testing (i.e., neural network model training data) is stored. The neural network model training data includes the same parameters as charge/discharge data for each charge/discharge cycle of the electric energy storage device. In other words, the neural network model training data is data including charge/discharge data of the electric energy storage device, collected in advance. Therefore, the neural network model training data includes voltage, current, temperature, capacitance, coulombic efficiency, etc. detected and acquired for each charge/discharge cycle of the electric energy storage device.

Further, similar to the charge/discharge data, the neural network model training data includes indicators and factors that are correlated with performance and deterioration of the electric energy storage device. In other words, the neural network model training data includes factors that affect SoH variation of the electric energy storage device. Additionally, in order to construct the SoH prediction neural network model for each driver type, the neural network model training data is stored for each driver type in the database.

The deep learning processor 30 is configured to execute neural network model training and evaluation of an electric energy storage device for constructing a neural network model having the same performance and characteristics as the electric energy storage device mounted in the vehicle 10 (i.e., an electric energy storage device for a vehicle). The deep learning processor 30 stores the built SoH prediction neural network model in the data server 20.

In other words, the deep learning processor 30 executes neural network model training for each driver type to construct an SoH prediction neural network model for each driver type. The deep learning processor 30 stores the SoH prediction neural network model determined to have achieved a target performance through neural network model evaluation in the data server 20. The deep learning processor 30 is communicatively connected to the data server 20, and the data server 20 is communicatively connected to the vehicle control unit 14. The data server 20 provides a predetermined SoH prediction neural network model to the vehicle control unit 14 at the request of the vehicle control unit 14. The data server 20 may be operated separately by a vehicle manufacturer.

In addition, the deep learning processor 30 may construct the SoH prediction neural network model through the process shown in FIG. 3 and may construct the SoH prediction neural network model for each driver type by repeatedly performing the neural network model constructing process for each driver type.

In order to execute the neural network model training, the deep learning processor 30 acquires neural network model training data necessary for constructing the SoH prediction neural network model from the database of the computing device.

In step S200 of FIG. 3, the deep learning processor 30 divides the neural network model training data into training data, validation data, and test data. The training data is used to learn a neural network model and fit parameters, and the validation data is used to validate whether overfitting or divergence occurred during the training process and to tune hyperparameters. Further, the test data is used to evaluate the final performance of the neural network model after training thereof.

In step S210, the deep learning processor 30 selects input parameters for neural network model training from the training data and the validation data. Then, in step S220, the deep learning processor 30 executes standard scaling on the input parameters to generate final input parameters for the neural network model training.

The input parameters have different units, and in a case where a difference between the units is large, it has a negative influence on the neural network model training. Therefore, the standard scaling process of setting the mean to 0 and the variance to 1 for the selected input parameters is performed. Through the standard scaling, the input parameters may be normalized to facilitate the neural network model training.

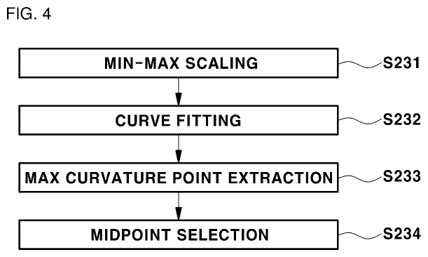

Then, in step S230, final output coordinates for neural network model training are selected based on the training and validation data. As shown in FIG. 4, the process of selecting the final output coordinates includes a min-max scaling process (S231), a curve fitting process (S232), and a maximum curvature point extraction process (S233), and a midpoint selecting process (S234).

In step S231, the min-max scaling is performed on the training and validation data for curve fitting to be performed in step S232. The training and validation data are normalized through the min-max scaling to facilitate the curve fitting to be performed in step S232. In the curve fitting process, the training and validation data are displayed as capacitance values on the Y axis for the charge/discharge cycle on the X axis. Here, in a case where a unit difference between the X-axis and Y-axis is relatively large, it has a negative influence on the curve fitting. Therefore, through the min-max scaling, the largest value in the ranges of the X and Y axes is adjusted to 1, and the smallest value is adjusted to 0.

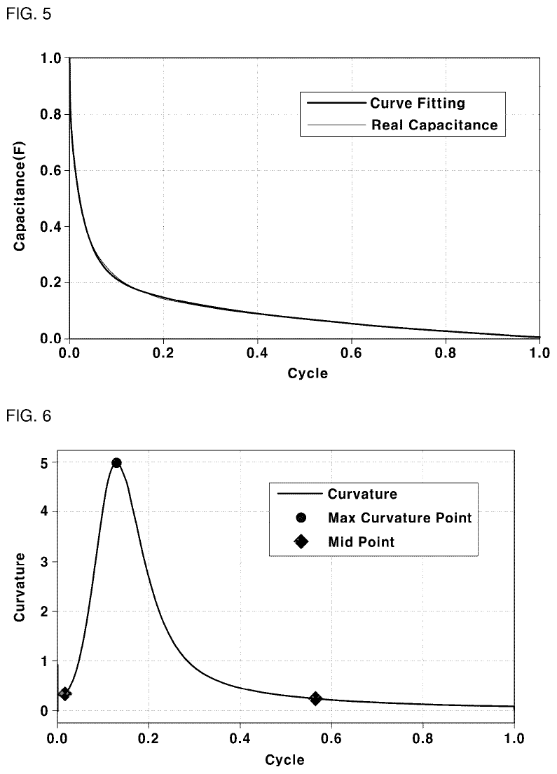

In step S232, the curve fitting is performed based on the training and validation data normalized in step S231 to determine a curve fitting function (see FIG. 5). Here, a smoothing and functionalization process is performed by fitting a real capacitance value among the normalized training and validation data to a curve fitting function (y) in Equation 1. Here, unknown values (i.e., a, b, c, d, e) in Equation 1 are determined.

$$y = {ax}^{b} + c {d}^{x} + e \qquad Equation 1$$

The curve fitting function of Equation 1 may be selected and changed by a designer who is performing the neural network model training. In the process of performing the curve fitting, the designer may design the curve fitting function in consideration of the distribution of the training data, the validation data, and the test data.

In step S233, a curvature (K) defined by Equation 2 is calculated based on the curve fitting function acquired through step S232, and the maximum value of the calculated curvature (i.e., the maximum curvature point of the curve fitting function) is extracted and determined (see FIG. 6).

$$K = \frac{\vert {x}^{″} {y}^{′} - {x}^{′} {y}^{″} \vert}{{( {( {x}^{′} )}^{2} + {( {y}^{′} )}^{2} )}^{\frac{3}{2}}} \qquad Equation 2$$

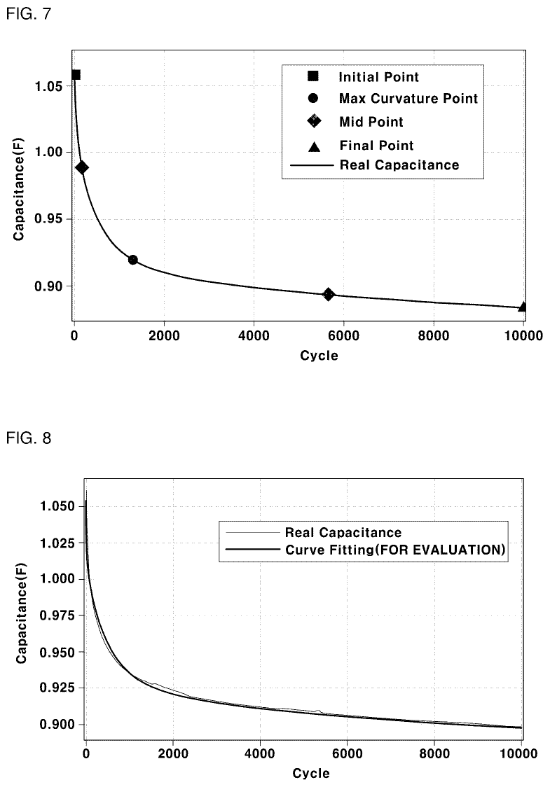

In step S234, a first midpoint and a second midpoint are selected using an initial curvature value (i.e., initial point), a final curvature value (i.e., final point), and the maximum curvature point among the curvature values calculated through Equation 2. The first and second midpoints are determined with reference to the maximum curvature point. Specifically, the first midpoint is selected as a curvature point between the initial point and the maximum curvature point, and the second midpoint is selected as a curvature point between the final point and the maximum curvature point. Final output coordinates are selected and determined from the curve fitting function based on the initial point, the final point, the maximum curvature point, and the charge/discharge cycle values at the first and second midpoints (see FIG. 7).

In this way, the final output coordinates for the neural network model training are generated and determined based on the curve fitting function acquired through step S232. The number of final output coordinates may be changed depending on the number of unknowns (i.e., a, b, c, d, e in Equation 1) of the curve fitting function and a design goal.

FIG. 5 shows a graph of the curve fitting function acquired in step S232, FIG. 6 shows a graph of the curvature (K) acquired in step S233. FIG. 7 is a diagram showing the final output coordinates for the neural network model training selected from the curve fitting function based on the midpoints selected in step S234.

Then, in step S240, the neural network model training is performed based on the final input parameters acquired through step S220 and the final output coordinates acquired through step S230. Through step S240, the training of the SoH prediction neural network model for predicting the SoH for each charge/discharge cycle of the electric energy storage device is performed. Here, the neural network model training includes a process of training an input-output relationship for predicting the SoH for each charge/discharge cycle.

The neural network model training is performed through supervised learning, which is a type of machine learning. Here, the final input parameters acquired in step S220 are generated based on the first charge/discharge data acquired from the training and the validation data and are selected as parameters that have a correlation with the SoH of the electric energy storage device. The final input parameters may be selected according to a target model of a designer. The final input parameters include coulombic efficiency, discharge current, temperature, initial capacitance, and voltage reduction during discharge, for example.

Then, in step S241, the training of the SoH prediction neural network model is completed, and the test input parameters generated in step S260 are input to the trained SoH prediction neural network model. In step S250 before step S260, the input parameters are selected from the test data.

In step S260, the standard scaling is performed on the input parameters, and the test input parameters are generated through the standard scaling process. The test input parameters are used as input parameters for performance evaluation of the trained SoH prediction neural network model.

The test input parameters generated in step S260 are input to the SoH prediction neural network model for which the training is completed in step S241, and the trained SoH prediction neural network model outputs prediction coordinates for predicting the SoH for each charge/discharge cycle (S270). The predicted coordinates represent capacitance values for each charge/discharge cycle of the electric energy storage device.

In step S280, the curve fitting is performed based on the predicted coordinates (i.e., capacitance values for each charge/discharge cycle) output from the trained SoH prediction neural network model, and an evaluation curve fitting function is generated through the curve fitting.

Then, in step S290, the capacitance values for each charge/discharge cycle of the evaluation curve fitting function are compared with real capacitance values for each charge/discharge cycle of the test data, and the performance of the trained SoH prediction neural network model is evaluated through the comparison result. In other words, the performance evaluation of the trained SoH prediction neural network model is performed based on the prediction coordinates (i.e., capacitance values for each charge/discharge cycle) output from the trained SoH prediction neural network model.

FIG. 8 is a diagram showing a result acquired by comparing the capacitance values of the evaluation curve fitting function generated with real capacitance values.

Next, in step S300, it is determined whether the target performance of the trained SoH prediction neural network model has been achieved through the performance evaluation performed in step S290. In a case where a determination is made that the target performance of the trained SoH prediction neural network model has been achieved (YES in step S300), the deep learning processor 30 stores the trained SoH prediction neural network model in the data server 20 (S310).

In a case where a determination is made that the target performance of the trained SoH prediction neural network model has not been achieved (NO in step S300), the deep learning processor 30 does not store the trained SoH prediction neural network model in the data server 20.

Additionally, in a case where a determination is made in step S300 that the target performance of the trained SoH prediction neural network model has not been achieved, hyperparameter tuning is performed in step S320.

In step S300, in a case where the difference value between the real capacitance and the capacitance of the evaluation curve fitting function (i.e., the evaluation capacitance) is within a predetermined error range based on the same charge/discharge cycle, it is determined that the target performance of the trained SoH prediction neural network model has been achieved. In a case where the difference value between the real capacitance and the evaluation capacitance exceeds the predetermined error range, it is determined that the target performance of the trained SoH prediction neural network model has not been achieved.

In addition, the hyperparameters are variables set in the model for optimal neural network model training and are set to ensure that a predicted value according to an input is reliably output during the process of training the input-output relationship of the neural network model.

For example, in the process of the neural network model training, there are various hyperparameters such as scheduling, epoch, optimizer, learning rate, loss function, and batch size. Because these hyperparameters determine the structure, function, and performance of the neural network model during the learning process, the optimal neural network model training may be performed again through the process of the hyperparameter tuning.

After the hyperparameter tuning is performed in step S320, the neural network model training is performed again in step S240. Through the hyperparameter tuning, optimal values of weighted variables for the neural network model training are updated. The neural network model training may be reliably performed by combining various hyperparameters that take hardware and target performance into account.

As described above, according to the present disclosure, it is possible to predict the SoH for the entire charge/discharge cycle of the electric energy storage device using only the first charge/discharge data of the electric energy storage device as input values of the SoH prediction neural network model. Thus, this dramatically shortens the performance evaluation time of the electric energy storage device with a very long lifespan compared with the related art.

In addition, according to the present disclosure, it is possible to early predict the SoH for each charging and discharging cycle of the electric energy storage device using the SoH prediction neural network model individually built according to the driver type. It is possible to continuously monitor the SoH during the driving of the vehicle. Thus, the power usage in vehicles is stable.

As the embodiments of the present disclosure have been described in detail above, the terms used in the present disclosure should not be construed as limited to their ordinary or dictionary meanings. The scope of the present disclosure is not limited to the above-described embodiments, and various modifications and improvements made by those having ordinary skill in the art using the basic concept of the present disclosure defined in the claims below are also included in the scope of the present disclosure.

The present disclosure has been described in detail with reference to embodiments thereof. However, it should be appreciated by those having ordinary skill in the art that changes may be made in these embodiments without departing from the principles and spirit of the present disclosure, the scope of which is defined in the appended claims and their equivalents.

What is claimed is:

1. A system for predicting a State of Health (SoH) of an electric energy storage device mounted in a vehicle, the system comprising:
a data collection unit configured to acquire charge/discharge data of the electric energy storage device; and
a vehicle control unit configured to
acquire an SoH prediction neural network model for predicting an SoH for each charge/discharge cycle of the electric energy storage device, based on first charge/discharge data of the electric energy storage device acquired by the data collection unit, and
predict and determine the SoH for each charge/discharge cycle of the electric energy storage device using the SoH prediction neural network model.

2. The system according to claim 1, wherein the vehicle control unit is further configured to:
determine a driver type based on a type of a road on which the vehicle travels; and
download a first SoH prediction neural network model among SoH prediction neural network models for respective driver types stored in a data server based on the determined driver type.

3. The system according to claim 2, wherein the vehicle control unit is further configured to download, in a case where a determination is made that the driver type has been changed during a driving of the vehicle, a second SoH prediction neural network model from the data server based on the changed driver type.

4. The system according to claim 1, further comprising:
a display device configured to display the SoH for each charge/discharge cycle of the electric energy storage device predicted by the vehicle control unit.

5. The system according to claim 4, wherein the display device is further configured to selectively display a replacement alarm for the electric energy storage device based on the SoH for each charge/discharge cycle of the electric energy storage device predicted by the vehicle control unit.

6. The system according to claim 4, wherein the vehicle control unit is further configured to:
determine a critical charge/discharge cycle for a replacement alarm for the electric energy storage device based on the SoH for each charge/discharge cycle of the electric energy storage device; and
output the replacement alarm for the electric energy storage device through the display device in a case where an actual charge/discharge cycle of the electric energy storage device is equal to or longer than the critical charge/discharge cycle.

7. The system according to claim 1, wherein the SoH prediction neural network model is preconfigured for each driver type through neural network model training and is stored in a data server.

8. A method of predicting a State of Health (SoH) of an electric energy storage device mounted in a vehicle, the method comprising:
acquiring, by a data collection unit, first charge/discharge data of the electric energy storage device;
acquiring, by a vehicle control unit, an SoH prediction neural network model for predicting an SoH for each charge/discharge cycle of the electric energy storage device, based on the first charge/discharge data; and
predicting and determining, by the vehicle control unit, the SoH for each charge/discharge cycle of the electric energy storage device using the acquired SoH prediction neural network model.

9. The method according to claim 8, further comprising:
displaying, by the vehicle control unit, the SoH for each charge/discharge cycle of the electric energy storage device predicted on a display device.

10. The method according to claim 9, further comprising:
determining, by the vehicle control unit, a critical charge/discharge cycle for a replacement alarm for the electric energy storage device based on the SoH for each charge/discharge cycle of the electric energy storage device; and
outputting, by the vehicle control unit, the replacement alarm for the electric energy storage device through the display device in a case where an actual charge/discharge cycle of the electric energy storage device is equal to or longer than the critical charge/discharge cycle.

11. The method according to claim 8, further comprising:
determining, by the vehicle control unit, a driver type based on a type of a road on which the vehicle travels;
downloading, by the vehicle control unit, a first SoH prediction neural network model among SoH prediction neural network models for respective driver types stored in a data server based on the determined driver type; and
predicting, by the vehicle control unit, the SoH for each charge/discharge cycle of the electric energy storage device using the first SoH prediction neural network model.

12. The method according to claim 11, further comprising:
downloading, by the vehicle control unit, in a case where a determination is made that the driver type has changed during driving, a second SoH prediction neural network model from the data server based on the changed driver type; and
predicting, by the vehicle control unit, the SoH for each charge/discharge cycle of the electric energy storage device using the second SoH prediction neural network model.

13. The method according to claim 8, further comprising:
preconfiguring, by a deep learning processor, the SoH prediction neural network model for each driver type through neural network model training and neural network model evaluation; and
storing, by a data server, the SoH prediction neural network model for each driver type.

14. The method according to claim 13, wherein the neural network model training by the deep learning processor comprises:
dividing neural network model training data into training data, validation data, and test data;
generating final input parameters for the neural network model training from the training data and the validation data;
determining a curve fitting function based on the training data and the validation data;
determining final output coordinates for the neural network model training based on the curve fitting function; and
performing training of the SoH prediction neural network model for predicting the SoH for each charge/discharge cycle of the electric energy storage device using the final input parameters and the final output coordinates for the neural network model training.

15. The method according to claim 14, wherein the neural network model evaluation by the deep learning processor comprises:
selecting test input parameters for evaluating the trained SoH prediction neural network model from the test data;
outputting prediction coordinates for predicting the SoH for each charge/discharge cycle of the electric energy storage device from the trained SoH prediction neural network model, based on the test input parameters;
executing performance evaluation of the trained SoH prediction neural network model based on the prediction coordinates output from the trained SoH prediction neural network model; and
storing, in a case where a determination is made through the performance evaluation that a target performance of the trained SoH prediction neural network model is achieved, the trained SoH prediction neural network model in the data server.
